(19) United States
(12) Patent Application Publication
(10) Pub. No.: US 2007/0018219 A1
(43) Pub. Date: Jan. 25, 2007

(54) Unit cell structure, method of manufacturing the same, non-volatile semiconductor device having the unit cell structure and method of manufacturing the non-volatile semiconductor device

(76) Inventors: Han-Jin Lim, Seoul (KR); Jung-Hyun Lee, Yongin-si (KR); Kyu-Ho Cho, Seongnam-si (KR); Jin-Il Lee, Seongnam-si (KR); Sung-Ho Park, Seongnam-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/480,547

(22) Filed: Jul. 5, 2006

(30) Foreign Application Priority Data
Jul. 5, 2005 (KR) 2005-59958

(51) Int. Cl. H01L 29/94

(52) U.S. Cl. 257/296

(57) ABSTRACT

A unit cell structure in a non-volatile semiconductor device includes a lower electrode. The variable resistor is formed on the lower electrode and includes a first insulation thin film, a third insulation thin film, and a second insulation thin film located between the first and third insulation thin films. A breakdown voltage of the second insulation thin film is lower than respective breakdown voltages of the first and third insulation thin films. An upper electrode is formed on the variable resistor.

### BACKGROUND OF THE INVENTION

1. Field of the Invention

Example embodiments of the present invention relate to a non-volatile semiconductor device and a method of manufacturing the non-volatile semiconductor device. More particularly, example embodiments of the present invention relate to a non-volatile semiconductor device including a variable resistor capable of storing data in accordance with a variation of resistances, and a method of manufacturing the non-volatile semiconductor device.

A claim of priority under 35 USC § 119 is made to Korean Patent Application No. 2005-59958 filed on Jul. 5, 2005, the contents of which are herein incorporated by reference in their entirety.

2. Description of the Related Art

Semiconductor memory devices are generally divided into volatile memory devices and non-volatile memory device. Volatile memory devices such as dynamic random access memory (DRAM) devices and static random access memory (SRAM) devices maintain data only when power is continuously supplied, whereas non-volatile memory devices such as ferroelectric random access memory (FRAM) devices, magnetic random access memory (MRAM) devices and phase-change random access memory (PRAM) devices maintain data stored therein even when supply of power is interrupted or turned off.

A resistor random access memory (RRAM) device has been recently developed as a type of non-volatile memory device. Generally, an RRAM device is characterized by changing resistance values relative to external conditions, and examples thereof are disclosed at U.S. Pat. No. 6,846,891 (issued to Hsu Sheng Teng, et al.) and U.S. Pat. No. 6,868,025 (issued to Hsu Sheng Teng), etc.

The RRAM device, which typically includes a lower electrode, an upper electrode and a variable resistor interposed there between, is programmed by application of voltages to the variable resistor to alter the resistance value thereof. However, conventional RRAM devices generally exhibit unstable programming characteristics, making mass production and reproducibility difficult on a manufacturing level.

### SUMMARY OF THE INVENTION

According to one aspect of the present invention, there is provided a unit cell structure in a non-volatile semiconductor device. The unit cell structure of the non-volatile semiconductor device includes a lower electrode, a variable resistor formed on the lower electrode and an upper electrode formed on the variable resistor. The variable resistor includes a first insulation thin film, a second insulation thin film and a third insulation thin film. The second insulation thin film is located between the first and third insulation thin films. A breakdown voltage of the second insulation thin film is lower than respective breakdown voltages of the first and third insulation thin films.

According to one aspect of the present invention, there is provided a method of manufacturing a unit cell structure in a non-volatile semiconductor device. In the method of manufacturing the unit cell structure in the non-volatile semiconductor device, after a lower electrode is formed, a variable resistor having a sandwich structure may be formed on the lower electrode. The variable resistor includes a first insulation thin film, a second insulation thin film and a third insulation thin film. The second insulation thin film is located between the first and third insulation thin films. A breakdown voltage of the second insulation thin film is lower than respective breakdown voltages of the first and third insulation thin films. An upper electrode may be formed on the variable resistor.

According to one aspect of the present invention, there is provided a unit cell structure in a non-volatile semiconductor device. The unit cell structure in the non-volatile semiconductor device includes a semiconductor substrate including a junction region doped with impurities. An insulating interlayer, which may include an opening exposing the junction region, may be formed on the semiconductor substrate. A plug, which is filling up the opening, may be electrically connected to the junction plug. A lower electrode, which is electrically connected to the plug may be formed on the insulating interlayer. The variable resistor which includes a first insulation thin film, a second insulation thin film and a third insulation thin film may be formed on the lower electrode. The second insulation thin film is located between the first and third insulation thin films. A breakdown voltage of the second insulation thin film is lower than respective breakdown voltages of the first and third insulation thin films. An upper electrode may be formed on the variable resistor.

According to one aspect of the present invention, there is provided a method of manufacturing a non-volatile semiconductor device. In the method of manufacturing the non-volatile semiconductor device, a junction region may be formed on a semiconductor substrate by doping impurities into the semiconductor substrate. An insulating interlayer including an opening exposing the junction region may be formed. A plug electrically connected to the junction plug may be formed by filling up the opening. A lower electrode electrically connected to the plug may be formed on the insulating interlayer. A variable resistor which includes a first insulation thin film, a second insulation thin film and a third insulation thin film may be formed on the lower electrode. The second insulation thin film is located between the first and third insulation thin films. A breakdown voltage of the second insulation thin film is lower than respective breakdown voltages of the first and third insulation thin films. An upper electrode may be formed on the variable resistor.

### BRIEF DESCRIPTION OF THE DRAWINGS

The above and other features and advantages of the present invention will become more apparent by describing in example embodiments thereof with reference to the accompanying drawings, in which:

FIG. 1 is a cross sectional view illustrating a unit cell structure of a non-volatile memory device in accordance with an example embodiment of the present invention;

FIG. 2 is a schematic circuit diagram illustrating a method of discriminating the unit cell structure of the non-volatile memory device in FIG. 1;

FIG. 3 is a graph illustrating currents relative to voltages applied to the unit cell structure of the non-volatile memory device in FIG. 1;

FIG. 4 is a graph illustrating reproducibility of the unit cell structure of the non-volatile memory device in FIG. 1;

FIG. 5 is a cross sectional view illustrating a non-volatile memory device in accordance with an example embodiment of the present invention;

FIGS. 6A to 6E are cross sectional views for use in explaining a method of manufacturing the non-volatile memory device in accordance with an example embodiment of the present invention; and

FIG. 7 is a cross sectional view illustrating a non-volatile memory device in accordance with an example embodiment of the present invention.

### DESCRIPTION OF THE EMBODIMENTS

The invention is described more fully hereinafter with reference to the accompanying drawings, in which example embodiments of the present invention are shown. The present invention may, however, be embodied in many different forms and should not be construed as limited to the example embodiments set forth herein. Rather, the example embodiments of the present invention are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Unit Cell Structure and Method of Manufacturing the Unit Cell Structure

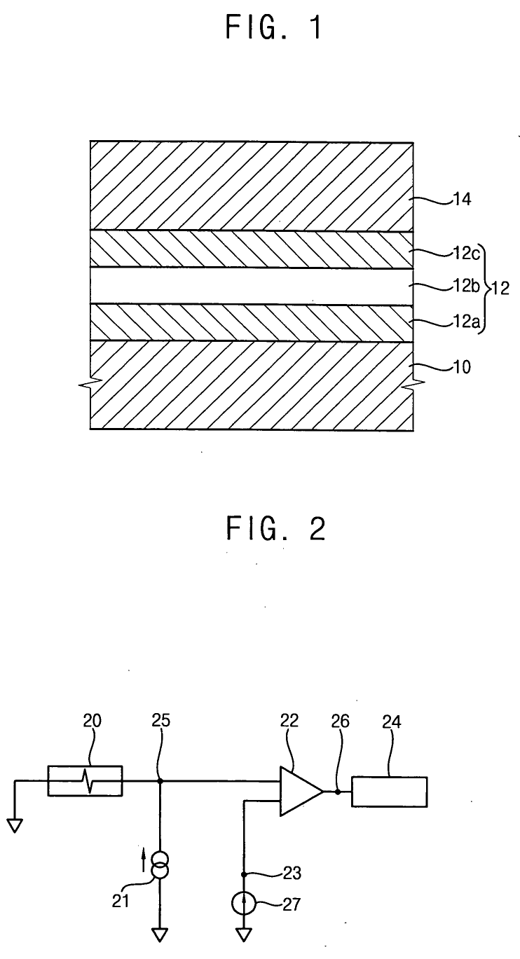

FIG. 1 is a cross sectional view illustrating a unit cell structure in a non-volatile semiconductor device in accordance with an example embodiment of the present invention.

Referring to FIG. 1, the non-volatile semiconductor device may correspond to a resistance random access memory (RRAM) device in an example embodiment of the present invention. The unit cell structure in the RRAM device includes a lower electrode 10, a variable resistor 12 and an upper electrode 14.

The lower electrode 10 may be formed on a semiconductor substrate such as, for example, a silicon substrate or a silicon-on-insulator (SOI) substrate. The semiconductor substrate may include a unit element such as a transistor, a metal wiring, a junction region, and other types of unit elements.

The lower electrode 10 may be formed by a chemical vapor deposition (CVD) process or an atomic layer deposition (ALD) process. In an example embodiment of the present invention, the lower electrode 10 may be formed by a CVD process to ensure a high productivity of the lower electrode 10.

The lower electrode 10 may be formed using a metal nitride and a noble metal. For example, the metal nitride may include titanium nitride, tantalum nitride, tungsten nitride, aluminum nitride, and/or titanium aluminum nitride. The noble metal may include ruthenium (Ru), iridium (Ir), platinum (Pt), palladium (Pd), rhodium (Rh), and/or osmium (Os). These can be used alone or a in a mixture of two or more thereof.

The variable resistor 12 is formed on the lower electrode 10. The variable resistor 12 includes a first insulation thin film 12a, a second insulation thin film 12b and a third insulation thin film 12c. In particular, the variable resistor 12 may have a sandwich structure including the first insulation thin film 12a, the third insulation thin film 12c, with the second insulation thin film 12b interposed between the first insulation thin film 12a and the third insulation thin film 12c.

The variable resistor 12 may have a thickness of about 50 Å to about 300 Å based on an upper face of the lower electrode 10. The variable resistor 12 may advantageously have a thickness of about 100 Å to about 200 Å. The variable resistor 12 may more advantageously have a thickness of about 150 Å to about 170 Å. When the variable resistor 12 has a thickness of about 160 Å, each of the first insulation thin film 12a and the third insulation thin film 12c may have a thickness of about 50 Å and the second insulation thin film 12b may have a thickness of about 60 Å.

The variable resistor 12 may be formed by an ALD process or a CVD process. Since the variable resistor 12 may be relatively thin at about 50 to about 300 Å, an ALD process may be preferred in spite of its low productivity.

The first insulation thin film 12a and the third insulation thin film 12c may include the same or substantially the same materials. In addition, each of the first insulation thin film 12a and the third insulation thin film 12c may have the same or substantially the same first breakdown voltages. However, the second insulation thin film 12b may have a second breakdown voltage substantially lower than the first breakdown voltage.

Each of the first insulation thin film 12a and the third insulation thin film 12c may include, for example, tantalum oxide, aluminum oxide, hafnium oxide, silicon oxide, or silicon oxynitride. These can be used alone or in a mixture of two or more thereof.

The second insulation thin film 12b may include, for example, niobium oxide, titanium oxide, nickel oxide, zirconium oxide, vanadium oxide, amorphous silicon, copper sulfide, PCMO ((Pr, Ca)MnO₃), chalcogenide, strontium titanium oxide, barium strontium titanium oxide, strontium zirconium oxide, barium zirconium oxide, and barium strontium zirconium oxide. These can be used alone or in a mixture of two or more thereof. In particular, when the second insulation thin film 12b includes a material having a perovskite crystal structure, the second insulation thin film 12b may include doped impurities such as, for example, chromium or manganese.

Further, the variable resistor 12 may have various shapes such as, for example, a vertically stacked structure or a cylindrical structure.

The upper electrode 14 is formed on the variable resistor 12. The upper electrode 14 may be formed by a CVD process or an ALD process.

The upper electrode 14 may include, for example, a metal nitride or a noble metal. The metal nitride may include, for example, titanium nitride, tantalum nitride, tungsten nitride, aluminum oxide, or titanium aluminum oxide. The noble metal may include, for example, ruthenium (Ru), Iridium (Ir), platinum (Pt), palladium (Pd), rhodium (Rh), or osmium (Os). These can be used alone or in a mixture of two or more thereof.

As described above, the unit cell structure 10 may have a sandwich structure that has the lower electrode 10, the upper electrode 14 and the variable resistor 12 interposed between the first and the upper electrodes 10 and 14. Therefore, when the unit cell structure is employed in the non-volatile semiconductor device such as the RRAM device, reproducibility of resistance characteristics of the variable resistor 12 may be secured.

Method of Discriminating a Unit Cell Structure

FIG. 2 is a circuit diagram illustrating a method of discriminating the unit cell structure in the non-volatile semiconductor device in FIG. 1.

As for the method of discriminating the unit cell structure in the non-volatile semiconductor device, a current or a voltage is initially applied to the unit cell structure and then a response value is measured. Comparing the response value with a standard value, a resistance status of the variable resistor is discriminated. When the voltage is applied to the unit cell structure, a current may be measured, whereas a voltage may be measured when the current is applied to the unit cell structure.

In more detail, referring to FIG. 2, when the unit cell structure is employed in an RRAM device, a voltage may be applied to the unit cell structure in the RRAM device to measure a current. For example, a voltage generated from a voltage source 21 is applied to the unit cell structure to generate a current from the unit cell structure 20. A comparator 22 compares the current 25 generated from the unit cell structure 20 with a reference current generated from a reference current source 27. Thus, the comparator 22 generates compared data to be stored in a storage unit 24. When the current 25 is lower than the reference current, a resistance status of the unit cell structure 20 is discriminated as a low status so that the storage unit 24 stores logic ‘0’. When the current 25 is higher than the reference current, a resistance status of the unit cell structure 20 is discriminated as a high status so that the storage unit 24 stores logic ‘1’.

According to an example embodiment of the present invention, a unit cell structure may have a variable resistance status such as a high status or a low status in accordance with a voltage or a current applied to the unit cell structure.

Evaluation of a Resistance Status of a Unit Cell Structure

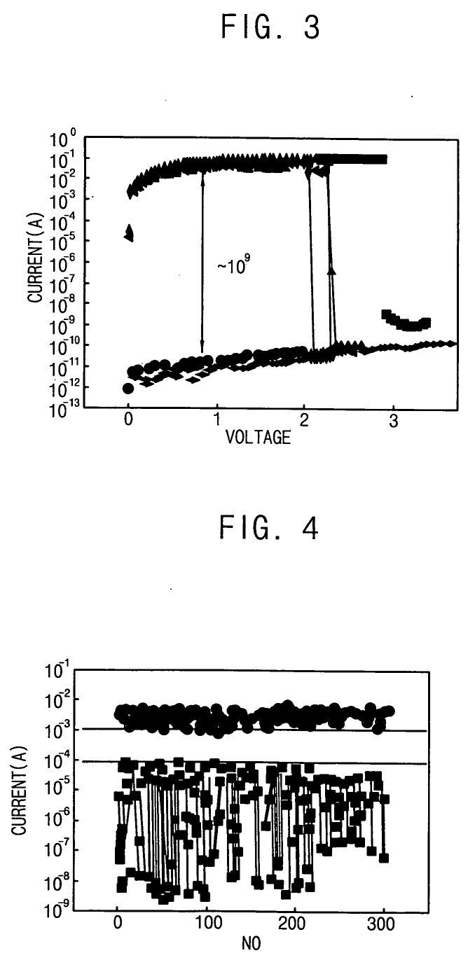

FIG. 3 is a graph illustrating currents relative voltages applied to the unit cell structure in the non-volatile semiconductor device in FIG. 1.

A sample of the unit cell structure was prepared in order to measure currents relative voltages applied to the unit cell structure as follows.

A platinum layer that works a lower electrode was initially prepared. A first tantalum oxide layer having a thickness of about 50 Å, a niobium oxide layer having a thickness of about 60 Å and a second tantalum oxide layer having a thickness of about 50 Å were sequentially formed on the platinum layer to form a variable resistor on the platinum layer. A ruthenium layer was formed on the variable resistor to form an upper electrode. As a result, the unit cell structure including the lower electrode having the platinum layer, the variable resistor having the first tantalum oxide layer, the niobium oxide layer and the second tantalum oxide layer, and the upper electrode having the ruthenium layer was prepared as the sample.

Referring to FIG. 3, a resistance status of the variable resistor was evaluated by measuring currents relative to voltage using the sample. As shown, the current values at a low resistance status of the variable resistor were significantly higher than the current values at a high resistance status of the variable resistor by 10E9.

Therefore, the unit cell structure including the sandwiched variable resistor may be advantageously employed in a non-volatile semiconductor device such as an RRAM device.

Evaluation of a Reproducibility of a Unit Cell Structure

FIG. 4 is a graph illustrating the reproducibility of the unit cell structure in the non-volatile semiconductor device in FIG. 1.

As shown in FIG. 3, a sample of the unit cell structure was prepared. The unit cell structure included a lower electrode having a platinum layer, a variable resistor having a first tantalum oxide layer, a niobium oxide layer and a second tantalum oxide layer, and an upper electrode having a ruthenium layer.

Referring to FIG. 4, after voltages were applied to the sample in excess of about 300 times, the current values at a low resistance status of the variable resistor were higher than the current values at a high resistance status of the variable resistor by a given gap.

Therefore, the unit cell structure including the sandwiched variable resistor may exhibit good reproducibility.

Non-volatile Semiconductor Device and Method of Manufacturing the Non-volatile Semiconductor Device

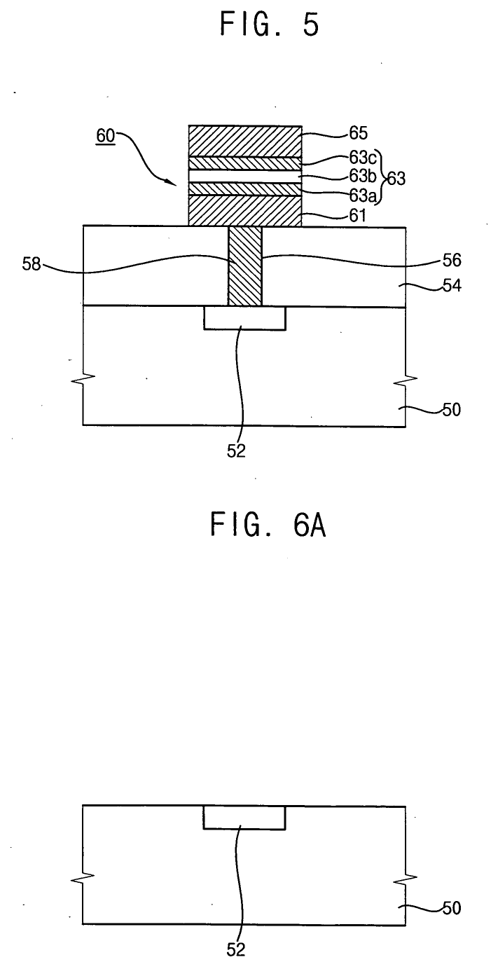

FIG. 5 is a cross sectional view illustrating a non-volatile semiconductor device in accordance with an example embodiment of the present invention.

Referring to FIG. 5, the non-volatile semiconductor device may correspond to a RRAM device including the unit cell structure in FIG. 1 in accordance with an example embodiment of the present invention. In an example embodiment of the present invention, the non-volatile semiconductor device may have a vertically stacked structure.

The RRAM device includes a semiconductor substrate 50, an insulating interlayer 54, a plug 58 and a unit cell structure 60.

The semiconductor substrate 50 includes a junction region 52 formed on a surface thereof. The semiconductor substrate 50 may include a silicon substrate or an SOI substrate. The junction region may be formed by an ion implantation process. That is, the junction region 52 may be formed by implanting impurities into a portion of the semiconductor substrate 50. For example, the impurities include boron (B) or phosphorus (P). These can be used alone or in combination.

Although not shown, an isolation layer may be formed on the semiconductor substrate 50. The isolation layer may divide the semiconductor substrate 50 into a field region and an active region. The isolation layer may include a filed oxide layer or a trench isolation layer. In an example embodiment of the present invention, the trench isolation layer may be formed on an upper portion of the semiconductor substrate 50 because the trench isolation layer may have an advantage relating to the integration degree of the semiconductor device. Further, various elements such as a transistor, a metal wiring, a junction region, and so forth may be formed on the semiconductor substrate 50.

An insulating interlayer 54 is formed on the semiconductor substrate 50. The insulating interlayer 54 includes an opening 56 through which the junction region 52 of the semiconductor substrate 50 is exposed. The insulating interlayer 54 may be formed, for example, using an oxide such as boro-phosphor silicate glass (BPSG), phosphor silicate glass (PSG), undoped silicate glass (USG), spin on glass (SOG), flowable oxide (FOX), plasma enhanced-tetraethylorthosilicate (PE-TEOS), or high density plasma-chemical vapor deposition (HDP-CVD) oxide. Additionally, the insulating interlayer 54 may be formed by a CVD process.

The plug 58 is formed on the insulating interlayer 54 to fill up the opening 56. The plug 58 includes a conductive material such as, for example, polysilicon, aluminum, tungsten, copper, titanium, or titanium nitride. These can be used alone or in a combination of two or more thereof. When the plug 58 includes titanium or titanium nitride, the plug 58 may also serve as a blocking layer. Further, the plug 58 may be formed by a deposition process and a planarizing process.

The unit cell structure 60 is formed on the insulating interlayer 54. The unit cell structure 60 includes a lower electrode 61 formed on the insulating interlayer 54, a variable resistor 63 formed on the lower electrode 61, and an upper electrode 65 formed on the variable resistor 63.

The lower electrode 61a is electrically connected to the junction region 52 through the plug 58. The variable resistor 63 may include a first insulation thin film 63a having a first breakdown voltage, a second insulation thin film 63b having a second breakdown voltage substantially lower than the first breakdown voltage, and a third insulation thin film 63c having the same or substantially the same material characteristics as the that of first insulation layer 63a. Therefore, in an example embodiment of the present invention, the variable resistor 63 may have a sandwich structure.

The lower electrode 61 may be formed by a CVD process or an ALD process. In an example embodiment of the present invention, the lower electrode 61 may be formed by the CVD process because of a high productivity for the lower electrode 61.

The lower electrode 61 may be formed using a metal nitride and a noble metal. For example, the metal nitride includes, for example, titanium nitride, tantalum nitride, tungsten nitride, aluminum nitride, titanium aluminum nitride, etc., and the noble metal includes ruthenium (Ru), iridium (Ir), platinum (Pt), palladium (Pd), rhodium (Rh), or osmium (Os). These can be used alone or a in a combination of two or more thereof.

The variable resistor 63 may have a sandwich structure. The variable resistor 63 may have a thickness of about 50 Å to about 300 Å. When the variable resistor 63 has a thickness of about 160 Å, each of the first insulation thin film 63a and the third insulation thin film 63c may have a thickness of about 50 Å and the second insulation thin film 63b may have a thickness of about 60 Å.

The variable resistor 63 may be formed by an ALD process or a CVD process. Since the variable resistor 63 is relatively thin, the ALD process may be preferred in spite of its low productivity.

Each of the first insulation thin film 63a and the third insulation thin film 63c may include, for example, tantalum oxide, aluminum oxide, hafnium oxide, silicon oxide, or silicon oxynitride. These can be used alone or in a combination of two or more thereof.

The second insulation thin film 63b may include, for example, niobium oxide, titanium oxide, nickel oxide, zirconium oxide, vanadium oxide, amorphous silicon, copper sulfide, PCMO ((Pr, Ca)MnO₃), chalcogenide, strontium titanium oxide, barium strontium titanium oxide, strontium zirconium oxide, barium zirconium oxide, or barium strontium zirconium oxide, etc. These can be used alone or in a combination of two or more thereof.

The upper electrode 65 is formed on the variable resistor 63. The upper electrode 65 may be formed by a CVD process or an ALD process. The upper electrode 65 may include, for example, a metal nitride or a noble metal.

In an example embodiment of the present invention, the variable resistor 63 is interposed between the lower electrode 61 and the upper electrode 65 so that the unit cell structure 60 has the sandwich structure. Thus, based on the evaluations described with reference to FIGS. 3 and 4, a resistance status of the variable resistor 63 may be divided into a low status and a high status to secure a sufficient reproducibility of the unit cell structure 60.

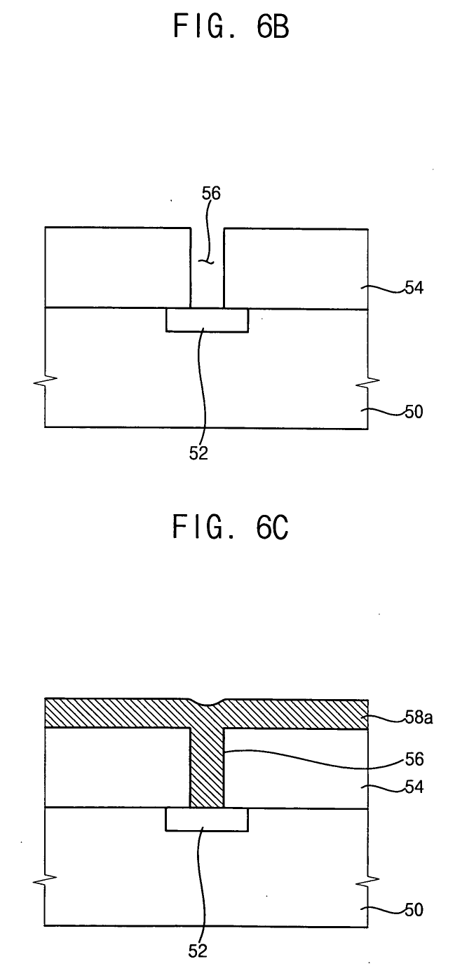

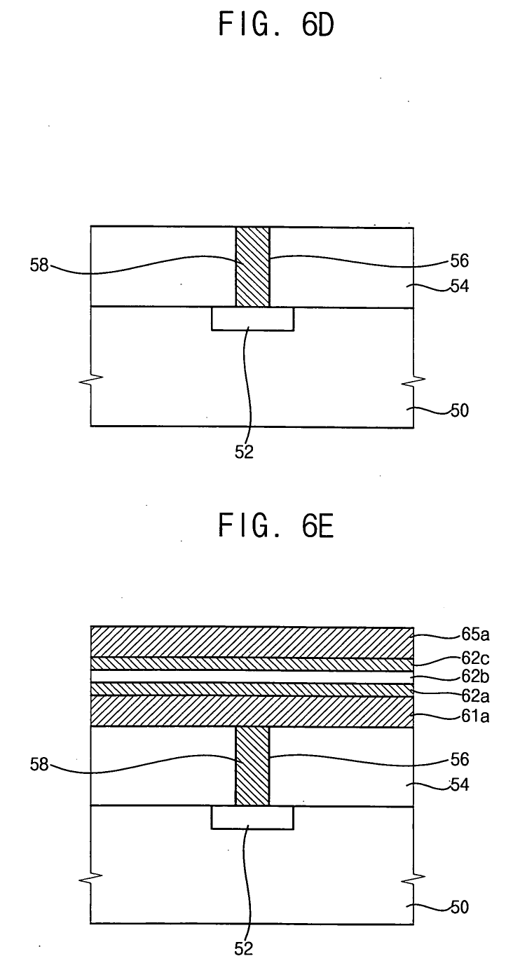

FIGS. 6A to 6E are cross sectional views illustrating a method of manufacturing the non-volatile semiconductor device in accordance with an example embodiment of the present invention.

Referring to FIG. 6, a semiconductor substrate 50 is provided. The semiconductor substrate 50 may include a silicon substrate or an SOI substrate.

Although not shown, an isolation layer such as a trench isolation layer may be formed on the semiconductor substrate 50. The isolation layer may divide the semiconductor substrate 50 into a field region and an active region. The trench isolation layer may have an advantage relating to integration degree of the semiconductor device.

A pad oxide layer and a pad nitride layer are sequentially formed on the semiconductor substrate 50, and then the pad oxide layer and the pad nitride layer are partially etched to form a pad oxide layer pattern and a pad nitride layer pattern on the semiconductor substrate 50.

The semiconductor substrate 50 is partially etched using the pad oxide layer pattern and the pad nitride layer pattern as an etching mask to form a trench at an upper portion of the semiconductor substrate 50. A curing process may be further performed on a sidewall of the trench for curing damage caused by a high-energy ion impact to the sidewall of the trench in the etching process for forming the trench.

An isolation layer 52 is formed on the semiconductor substrate 50 to fill up the trench. The isolation layer 52 may be formed by an isolation process such as a shallow trench isolation (STI) process or a local oxidation of silicon (LOCOS) process. In an example embodiment of the present invention, the isolation layer 52 may be formed by the STI process.

According to the STI process, an oxide layer may be formed using an oxide having good gap filling characteristics such as HDP oxide. The oxide layer including HDP oxide may be formed by a plasma enhanced chemical vapor deposition (PECVD) process. The oxide layer may be then planarized until an upper face of the pad nitride layer pattern is exposed. The oxide layer may be planarized by a chemical mechanical polishing (CMP) process, an etch back process or a combination process of CMP and etch back. The pad nitride layer pattern and the pad oxide layer pattern are removed from the semiconductor substrate 50. The pad nitride layer pattern and the pad oxide layer pattern may be removed by an etching process using an etchant containing phosphoric acid. Thus, the isolation layer 52 is formed on the upper portion of the semiconductor substrate 50 to fill up the trench.

A junction region 52 doped with impurities is formed on the semiconductor substrate 50. The junction region 52 may be formed in the active region defined by the trench isolation layer. The junction region 52 may be formed by an ion implantation process. The impurities such as boron (B) or phosphorus (P) may be implanted into the semiconductor substrate 50 to form the junction region 52. When the semiconductor device includes an NMOS transistor, the impurities may include boron. However, when the semiconductor device includes a PMOS transistor, the impurities may include phosphorus.

Although not shown, various elements such as a transistor, a metal wiring or a junction region may be formed on the semiconductor substrate 50.

Referring to FIG. 6B, an insulating interlayer 54 is formed on the semiconductor substrate 50. The insulating interlayer 54 may be formed, for example, using an oxide such as boro-phosphor silicate glass (BPSG), phosphor silicate glass (PSG), undoped silicate glass (USG), spin on glass (SOG), flowable oxide (FOX), plasma enhanced-tetraethylorthosilicate (PE-TEOS), or high density plasma-chemical vapor deposition (HDP-CVD) oxide. The insulating interlayer 54 may be formed by a CVD process.

After the insulating interlayer 54 is formed on the semiconductor substrate 50, the insulating interlayer 54 is partially etched to form an opening 56 that exposes the junction region 53 of the semiconductor substrate 50. In detail, a photoresist pattern (not shown) may be formed on the insulating interlayer 54 to expose a portion of the insulating interlayer 54 over the junction region 52. The exposed portion of the insulating interlayer 54 is etched using the photoresist pattern as an etching mask to form the opening 56 exposing the junction region 53 of the semiconductor substrate 50.

Referring to FIG. 6C, a conductive layer 58a is formed on the insulating interlayer 54 to fill up the opening 56.

The conductive layer 58a may be formed, for example, using polysilicon, aluminum, tungsten, copper, titanium, or titanium nitride. These can be used alone or in a combination of two or more thereof. Particularly, when the conductive layer 58a includes titanium or titanium nitride, the conductive layer 58a may work as a blocking layer continuously formed on a sidewall and a lower face of the opening 56. The conductive layer 58a may be formed by a CVD process or a sputtering process.

When the conductive layer 58a may be formed only in the opening 56, a subsequent planarizing process may be omitted. However, in an actual fabrication process, forming the conductive layer 58a only in the opening 56 may difficult to realize, and thus subsequent planarization may be necessary.

Referring to FIG. 6D, the conductive layer 58a is planarized until an upper face of the insulating interlayer 54 is exposed to thereby form a plug 58 on the semiconductor substrate 50 to fill up the opening 56. The conductive layer 58a may be planarized by a CMP process, an etch back process or a combination process of CMP and etch back. The plug 58 is electrically connected to the junction region 52 of the semiconductor substrate 50.

Referring to FIG. 6E, thin films 61a, 62a, 62b, 62c and 65a for forming a lower electrode, a variable resistor and an upper electrode are sequentially formed on the insulating interlayer 54 having the plug 58.

A first conductive thin film 61a is formed on the insulating interlayer 54 having the plug 58. The first conductive thin film 61a may be formed by a CVD process. The first conductive thin film 61a may be formed using a metal nitride or a metal. For example, the metal nitride includes, for example, titanium nitride, tantalum nitride, tungsten nitride, aluminum nitride, titanium aluminum nitride, etc. The metal includes ruthenium (Ru), iridium (Ir), platinum (Pt), palladium (Pd), rhodium (Rh), or osmium (Os).

A first insulation thin film 62a is formed on the first conductive thin film 61a. The first insulation thin film 62a may be formed by an ALD process. The first insulation thin film 62a may be formed using a material having a relatively low breakdown voltage such as, for example, tantalum oxide, aluminum oxide, hafnium oxide, silicon oxide, or silicon oxynitride.

In an example embodiment of the present invention, the first insulation thin film 62a including tantalum oxide may be formed by an ALD process as follows.

The semiconductor substrate 50 is initially loaded in a chamber. When an inner temperature of the chamber is below about 200° C., a reactivity of reactants may be lower. When the inner temperature of the chamber is over about 600° C., the first insulation thin film 62a including tantalum oxide may be crystallized. Therefore, the chamber may have the inner temperature of 200° C. to about 600° C. Further, when an inner pressure of the chamber is below about 0.1 Torr, the reactivity of the reactants may be lower. When the inner pressure of the chamber is over about 3.0 Torr, processing conditions may not be easily controlled. Thus, the chamber may have the inner pressure of about 0.1 Torr to about 3.0 Torr.

After adjusting the processing conditions having the above temperature and pressure, reactants are provided onto the first conductive thin film 61a of the semiconductor substrate 50 loaded in the chamber. When the first insulation thin film 62a is formed using tantalum oxide, the reactant may include tantalum precursors. The reactant may be provided onto the first conductive thin film 61a of the semiconductor substrate 50 for about 0.5 to about 3 seconds.

The reactant is provided onto the first conductive thin film 61a. A first portion of the reactant may be chemically absorbed (i.e., chemisorbed) to the first conductive thin film 61a. A second portion of the reactant may be physically absorbed (i.e., physisorbed) to the chemisorbed first portion of the reactant or may be drifted in the chamber.

A first purge gas is provided onto the substrate. The first purge gas may include an inactive gas such as an argon (Ar) gas. The first purge gas may be introduced into the chamber for about 0.5 to about 20 seconds. When the first purge gas is introduced into the chamber, the second portion of the reactant is removed from the chamber. That is, the physorbed portion of the reactant and the drifting portion of the reactant are removed from the chamber by providing the first purge gas into the chamber. As a result, the chemisorbed first portion of the reactant including tantalum precursor molecules may remain on the first conductive thin film 61a.

An oxidant is introduced into the chamber 1 for about one to about seven seconds. The oxidant may include ozone (O₃), oxygen (O₂), water (H₂O) vapor, plasma oxygen, remote plasma oxygen, etc. These can be used alone or in a mixture thereof. When the oxidant may be provided onto the first conductive thin film 61a, the tantalum precursor molecules in the chemisorbed first portion of the reactant are chemically reacted with the oxidant to oxidize the tantalum precursor molecules.

A second purge gas is introduced into the chamber. A type and a feeding time of the second purge gas may be substantially to the same as those of the first purge gas. When the second purge gas is introduced onto the chamber, a remaining oxidant may be removed from the first insulation thin film 62a. Thus, a solid layer including tantalum oxide is formed on the first conductive thin film 61a.

In an example embodiment of the present invention, the first insulation thin film 62a including tantalum oxide may be formed on the first conductive thin film 61a having a desired thickness by repeatedly performing the process of providing the reactant, introducing the first purge gas, providing the oxidant and introducing the second purge gas.

A second insulation thin film 62b is formed on the first insulation thin film 62a. The second insulation thin film 62b may be formed by an ALD process. The second insulation thin film 62b of the variable resistor may have a breakdown voltage substantially lower than that of the first insulation thin film 62a. The second insulation thin film 62b may be formed using an insulating material. For example, the insulating material includes, for example, niobium oxide, titanium oxide, nickel oxide, zirconium oxide, vanadium oxide, amorphous silicon, copper sulfide, PCMO ((Pr, Ca)MnO₃), chalcogenide, strontium titanium oxide, barium strontium titanium oxide, strontium zirconium oxide, barium zirconium oxide, or barium strontium zirconium oxide. These can be used alone or in a combination of two or more thereof.

A method for forming the second insulation thin film 62b is substantially same as the method for forming the first insulation thin film 62a except for the reactant utilized. Thus, any further descriptions of the method for the second insulation thin film 62b will be omitted.

A third insulation thin film 62c is formed on the second insulation thin film 62b. The third insulation thin film 62c may be the same as or substantially the same as the first insulation thin film 62a. Thus, a method of forming the third insulation thin film 62c may be the same as or substantially the same as the method of forming the first insulation thin film 62a.

As described above, the first insulation thin film 62a, the second insulation thin film 62b and the third insulation thin film 62c, which may be employed to the variable resistor, are sequentially formed on the first conductive thin film 61a. An overall thickness of the first insulation thin film 62a, the second insulation thin film 62b and the third insulation thin film 62c may be in a range of about 50 Å to about 300 Å. In detail, each of the first and the third insulation thin films 62a and 62c may be about 0.5 to about 0.9 times thicker than that of the second insulation thin film 62b. For example, when the overall thickness is about 160 Å, each of the first and the third insulation thin films 62a and 62c may have a thickness of about 50 Å and the second insulation thin film 63b may have a thickness of about 60 Å.

A second conductive thin film 65a is formed on the third insulation thin film. The second conductive thin film 65a may be formed by a CVD process. The second conductive thin film 65a may be formed using a material which is the same as or substantially the same as that of the first conductive thin film 61a. The first conductive thin film 61a may be formed using a metal nitride or a metal. For example, the metal nitride includes titanium nitride, tantalum nitride, tungsten nitride, aluminum nitride, titanium aluminum nitride, etc. and the metal includes ruthenium (Ru), iridium (Ir), platinum (Pt), palladium (Pd), rhodium (Rh), or osmium (Os).

Accordingly, the first conductive thin film 61a, the first insulation thin film 62a, the second insulation thin film 62b, the third insulation thin film 62c and the second conductive thin film 65a are sequentially formed on the insulating interlayer 54 including the plug 58.

The first conductive thin film 61a, the first insulation thin film 62a, the second insulation thin film 62b, the third insulation thin film 62c and the second conductive thin film 65a are sequentially and partially etched to form an lower electrode 61, a variable resistor 63 and an upper electrode 65 on the insulating interlayer 54. The lower electrode 61 is electrically connected to the junction region 52 through the plug 58. The variable resistor 53 includes the first insulation thin film 63a, the second insulation thin film 63b and the third insulation thin film 63c. Thus, the variable resistor 53 may have a sandwich structure.

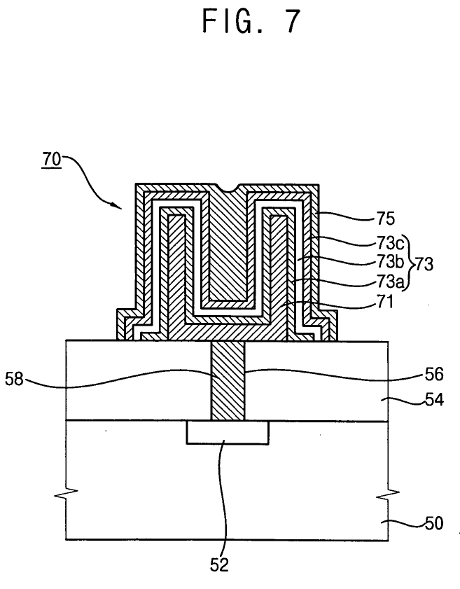

FIG. 7 is a cross sectional view illustrating a non-volatile memory device in accordance with an example embodiment of the present invention. In an example embodiment of the present invention, the non-volatile semiconductor device may have a cylindrical structure.

Referring to FIG. 7, a unit cell structure 70 includes a lower electrode 71, a variable resistor 73 formed on the lower electrode 71, and an upper electrode 75 formed on the variable resistor 73.

The variable resistor 73 includes a first insulation thin film 73a a second insulation thin film 73b and the third insulation thin film 73c. The first insulation thin film 73a may have a relatively low first breakdown voltage. The second insulation thin film 73b may have a second breakdown voltage substantially higher than the first breakdown voltage. The third insulation thin film 73c may include a material which is the same as or substantially the same as that of the first insulation thin film 73a.

When an RRAM device includes the unit cell structure 70 having the cylindrical structure, the RRAM device may have a function substantially similar to that of the RRAM device including the unit cell structure 70 having the vertically stacked structure in FIG. 5.

A method of manufacturing the RRAM device including the unit cell structure 70 having the cylindrical structure will be described as follows.

An insulating interlayer 54 including an first opening 56 is formed on the semiconductor substrate 50 and a plug 58 electrically connected to a junction region 52 is formed to fill up the first opening 56 by the processes described with reference to FIGS. 6A to 6D.

A mold layer (not shown) may be formed on the insulating interlayer 54. The mold layer may be formed using an oxide by a CVD process. The mold layer may be partially etched to form the first opening 56 through which an upper face of the plug 58 is exposed.

Particularly, a photoresist film (not shown) may be formed on the mold layer and then the photoresist film may be partially etched by a photolithographic process to form a photoresist pattern (not shown) exposing a portion of the mold layer. The exposed portion of the mold layer may be positioned over the exposed upper face of the plug 58. The mold layer may be partially etched using the photoresist pattern as an etching mask to remove the exposed portion of the mold layer. Thus, the mold layer having a second opening, through which the plug 58 is exposed, may be formed on the insulating interlayer 54.

The first conductive thin film may be continuously formed on a sidewall and a lower face of the second opening and a mold layer. A method of forming the first conductive thin film may be substantially the same as the method described with reference to FIG. 6D. Thus, the first conductive thin film may be formed by a CVD process.

A sacrificial layer (not shown) may be formed on the first conductive thin film. The sacrificial layer may be formed on the first conductive thin film to fill up the second opening. The sacrificial layer may be formed using a material having an etching selectivity relative to the mold layer.

After the sacrificial layer is formed, the sacrificial layer may be planarized until an upper face of the mold layer is exposed to form a first conductive thin film node separated on an inner wall of the second opening, and a planarized mold layer remaining in the second opening. The sacrificial layer may be planarized by a chemical mechanical polishing (CMP) process, an etch back process or a combination process of CMP and etch back.

The mold layer and the sacrificial layer that remain on the semiconductor substrate 50 may be removed from the semiconductor substrate 50. Thus, the lower electrode 71, which is electrically connected to the junction region 52 through the plug 58, is formed on the insulating interlayer 54. That is, the node separated first conductive thin film may correspond to the lower electrode 71 having the cylindrical structure.

A first insulation thin film, a second insulation thin film, a third insulation thin film and a second conductive thin film may be sequentially formed on the first electrode 71 having the cylindrical structure and then the second insulation thin film, the third insulation thin film and the second conductive thin film may be patterned to form a unit cell structure 70 having the cylindrical structure on the semiconductor substrate 50.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following

What is claimed is:

1. A unit cell structure in a non-volatile semiconductor device comprising:
a lower electrode;
a variable resistor formed on the lower electrode, the variable resistor comprising a first insulation thin film, a second insulation thin film and a third insulation thin film, wherein the second insulation thin film is located between the first and third insulation thin films, and wherein a breakdown voltage of the second insulation thin film is lower than repective breakdown voltages of the first and third insulation thin films; and
an upper electrode formed on the variable resistor.

2. The unit cell structure of claim 1, wherein the lower electrode and the upper electrode independentally comprise a metal nitride, a noble metal or a mixture of the metal nitride and the noble metal.

3. The unit cell structure of claim 2, wherein the metal nitride comprises at least one selected from the group consisting of titanium nitride, tantalum nitride, tungsten nitride, aluminum nitride and titanium aluminum nitride, and the noble metal includes at least one selected from the group consisting of ruthenium, iridium, platinum, palladium, rhodium and osmium.

4. The unit cell structure of claim 1, wherein the variable resistor has a vertically stacked structure or a cylindrical structure.

5. The unit cell structure of claim 1, wherein the variable resistor has a thickness of about 50 Å to about 300 Å.

6. The unit cell structure of claim 1, wherein each of the first and the third insulation thin films independentally comprises at least one selected from the group consisting of tantalum oxide, aluminum oxide, hafnium oxide, silicon oxide and silicon oxynitride, and
wherein the second insulation thin film comprises at least one selected from the group consisting of niobium oxide, titanium oxide, nickel oxide, zirconium oxide, vanadium oxide, amorphous silicon, copper sulfide, PCMO ((Pr, Ca)MnO₃), chalcogenide, strontium titanium oxide, barium strontium titanium oxide, strontium zirconium oxide, barium zirconium oxide and barium strontium zirconium oxide.

7. A method of manufacturing a unit cell structure in a non-volatile semiconductor device comprising:
forming a lower electrode;
forming a variable resistor formed on the lower electrode, the variable resistor comprising a first insulation thin film, a second insulation thin film and a third insulation thin film, wherein the second insulation thin film is located between the first and third insulation thin films, and wherein a breakdown voltage of the second insulation thin film is lower than repective breakdown voltages of the first and third insulation thin films; and
forming an upper electrode on the variable resistor.

8. The method of claim 7, wherein the lower and the upper electrodes are formed by chemical vapor deposition processes.

9. The method of claim 7, wherein the lower and the upper electrodes independentally comprise a metal nitride, a noble metal or a mixture of the nitride and the noble metal.

10. The method of claim 9, wherein the metal nitride comprises at least one selected from the group consisting of titanium nitride, tantalum nitride, tungsten nitride, aluminum nitride and titanium aluminum nitride, and the noble metal includes at least one selected from the group consisting of ruthenium, iridium, platinum, palladium, rhodium and osmium.

11. The method of claim 7, wherein the variable resistor is formed by an atomic layer deposition process.

12. The method of claim 7, wherein the variable resistor has a thickness of about 50 Å to about 300 Å.

13. The method of claim 7, wherein the first and the third insulation thin films independentally comprise at least one selected from the group consisting of tantalum oxide, aluminum oxide, hafnium oxide, silicon oxide and silicon oxynitride, and
wherein the second insulation thin film comprises at least one selected from the group consisting of niobium oxide, titanium oxide, nickel oxide, zirconium oxide, vanadium oxide, amorphous silicon, copper sulfide, PCMO ((Pr, Ca)MnO₃), chalcogenide, strontium titanium oxide, barium strontium titanium oxide, strontium zirconium oxide, barium zirconium oxide and barium strontium zirconium oxide.

14. A non-volatile semiconductor device comprising:
a semiconductor substrate including a junction region doped with impurities;
an insulating interlayer formed on the semiconductor substrate, the insulating interlayer including an opening that exposes the junction region;
a plug filling up the opening, the plug being electrically connected to the junction plug;
a lower electrode formed on the insulating interlayer, the lower electrode being electrically connected to the plug;
a variable resistor formed on the lower electrode, the variable resistor comprising a first insulation thin film, a second insulation thin film and a third insulation thin film, wherein the second insulation thin film is located between the first and third insulation thin films, and wherein a breakdown voltage of the second insulation thin film is lower than repective breakdown voltages of the first and third insulation thin films; and
an upper electrode formed on the variable resistor.

15. The non-volatile memory device of claim 14, wherein the impurities of the junction region comprise boron, phosphorus or a mixture of boron and phosphorus.

16. The non-volatile memory device of claim 14, wherein the plug comprises at least one selected from the group consisting of polysilicon, aluminum, tungsten, copper, titanium and titanium nitride.

17. The non-volatile memory device of claim 14, wherein the lower electrode and the upper electrode independentally comprise a metal nitride, a noble metal or a mixture of the metal nitride and the noble metal.

18. The non-volatile memory device of claim 17, wherein the metal nitride comprises at least one selected from the group consisting of titanium nitride, tantalum nitride, tungsten nitride, aluminum nitride and titanium aluminum nitride, and the noble metal includes at least one selected from the group consisting of ruthenium, iridium, platinum, palladium, rhodium and osmium.

19. The non-volatile memory device of claim 14, wherein the variable resistor has a vertically stacked structure or a cylindrical structure.

20. The non-volatile memory device of claim 14, wherein the variable resistor has a thickness of about 50 Å to about 300 Å.

21. The non-volatile memory device of claim 14, wherein the first and the third insulation thin films independentally comprise at least one selected from the group consisting of tantalum oxide, aluminum oxide, hafnium oxide, silicon oxide and silicon oxynitride, and
wherein the second insulation thin film comprises at least one selected from the group consisting of niobium oxide, titanium oxide, nickel oxide, zirconium oxide, vanadium oxide, amorphous silicon, copper sulfide, PCMO ((Pr, Ca)MnO₃), chalcogenide, strontium titanium oxide, barium strontium titanium oxide, strontium zirconium oxide, barium zirconium oxide and barium strontium zirconium oxide.

22. A method of manufacturing a non-volatile semiconductor device comprising:
forming a junction region on a semiconductor substrate by doping impurities into the semiconductor substrate;
forming an insulating interlayer on the semiconductor substrate, the insulating interlayer including an opening that exposes the junction region;
forming a plug electrically connected to the junction plug by filling up the opening;
forming a lower electrode electrically connected to the plug on the insulating interlayer;
forming a variable resistor formed on the lower electrode, the variable resistor comprising a first insulation thin film, a second insulation thin film and a third insulation thin film, wherein the second insulation thin film is located between the first and third insulation thin films, and wherein a breakdown voltage of the second insulation thin film is lower than repective breakdown voltages of the first and third insulation thin films; and
forming an upper electrode on the variable resistor.

23. The method of claim 22, wherein forming the junction region comprises implanting the impurities including boron, phosphorus or a mixture of boron and phosphorus into the semiconductor substrate.

24. The method of claim 22, wherein forming the plug comprises;
forming a conductive layer on the insulating interlayer having the opening, the conductive layer including at least one selected from the group consisting of polysilicon, aluminum, tungsten, copper, titanium and titanium nitride; and
planarizing the conductive layer until an upper face of the insulating interlayer is exposed.

25. The method of claim 22, wherein the lower and the upper electrodes are formed by chemical vapor deposition processes.

26. The method of claim 22, wherein the lower electrode and the upper electrode independentally comprise a metal nitride, a noble metal or a mixture of the metal nitride and the noble metal.

27. The method of claim 26, wherein the metal nitride comprises at least one selected from the group consisting of titanium nitride, tantalum nitride, tungsten nitride, aluminum nitride and titanium aluminum nitride, and the noble metal includes at least one selected from the group consisting of ruthenium, iridium, platinum, palladium, rhodium and osmium.

28. The method of claim 22, wherein the variable resistor is formed by an atomic layer deposition process.

29. The method of claim 22, wherein the variable resistor has a thickness of about 50 Å to about 300 Å.

30. The method of claim 22, wherein the first and the third insulation thin films independentally comprises at least one selected from the group consisting of tantalum oxide, aluminum oxide, hafnium oxide, silicon oxide and silicon oxynitride, and
wherein the second insulation thin film comprises at least one selected from the group consisting of niobium oxide, titanium oxide, nickel oxide, zirconium oxide, vanadium oxide, amorphous silicon, copper sulfide, PCMO ((Pr, Ca)MnO₃), chalcogenide, strontium titanium oxide, barium strontium titanium oxide, strontium zirconium oxide, barium zirconium oxide and barium strontium zirconium oxide.
